(19) United States
(12) Patent Application Publication
(10) Pub. No.: US 2025/0271121 A1
(43) Pub. Date: Aug. 28, 2025

(54) POWER CONVERTER WITH DISPLAY

(71) Applicant: Anker Innovations Technology Co., Ltd., Changsha (CN)

(72) Inventors: Tujin Chen, Shenzhen (CN); Yi Ouyang, Shenzhen (CN)

(21) Appl. No.: 19/063,727

(22) Filed: Feb. 26, 2025

(30) Foreign Application Priority Data
Feb. 27, 2024 (CN) 202420369918.2

(51) Int. Cl. F21V 11/00; F21V 13/10; F21W 111/00; H05K 5/02

(52) U.S. Cl. CPC F21V 11/00; F21V 13/10; H05K 5/0217; F21W 2111/00

(57) ABSTRACT

A power converter may comprise converter circuitry, a housing and a display. The converter circuitry is configured to convert electrical energy. The housing may comprise a mounting groove. The display may comprise a display screen provided in the mounting groove and a protective layer covering the mounting groove. The protective layer may have a translucent area and an opaque area adjacent to the translucent area. The display screen may comprise a display area located corresponding to the translucent area, and a projection of the translucent area toward the display screen may cover the display area.

### CROSS-REFERENCE OF RELATED APPLICATION

The present application claims priority to CN 202420369918.2, filed on Feb. 27, 2024, which is incorporated by reference by its entirety.

### FIELD

The present disclosure relates to the technical field of energy storage systems, in particular to a converter (e.g., power converter).

### BACKGROUND

With the development of science and technology, energy storage systems and power generation systems are constantly updated and developed, bringing convenience to people's lives. For example, domestic solar power generation systems can provide electricity for family life. As another example, mobile energy storage systems can facilitate people to use a variety of electrical appliances outdoors.

In a working process of the energy storage system and power generation system, converters are often needed to convert current. For example, electronic devices such as converters are needed to convert between direct current (DC) and alternating current (AC). A converter can be equipped with a display screen to display various kinds of work-related information, but the current display effect of the display screen needs to be improved.

### SUMMARY

A technical problem mainly solved by the present disclosure is to provide a converter with an improved display effect of a display area of a display screen.

In order to solve the technical problem, a technical solution adopted by the disclosure is as follows. A power converter with an improved display is provided. For example, a power converter may comprise converter circuitry, a housing and a display. The converter circuitry is configured to convert electrical energy. The housing may comprise a mounting groove. The display may comprise a display screen provided in the mounting groove and a protective layer covering the mounting groove. The protective layer may have a translucent area and an opaque area adjacent to the translucent area. The display screen may comprise a display area located corresponding to the translucent area, and a projection of the translucent area toward the display screen may cover the display area

Beneficial effects of the disclosure are: different from the power converters in the related art, a part of the protective layer used with the display screen is set to be translucent, and the other part thereof is set to be opaque, thereby forming a translucent area and an opaque shielding area. The translucent area can allow the lighted characters and images on the display area to be seen by one or more users, and the translucent area can also shield the unlighted characters and images on the display area, thus limiting visual interference caused by the unlighted characters and images and making the lighted characters and images stand out, thereby improving the display effect of the display area and facilitating the users to clearly observe the display information on the display area.

### BRIEF DESCRIPTION OF THE DRAWINGS

FIG. 1 is a three-dimensional structure diagram of a converter according to an example of the present disclosure;

FIG. 2 is a front view of the converter according to an example of the disclosure;

FIG. 3 is a three-dimensional structure diagram of the converter whose surface cover and display module are not assembled according to an example of the present disclosure;

FIG. 4 is a cross-sectional structure diagram cut along a line D-D of the converter shown in FIG. 2 with part of components hidden;

FIG. 5 is a schematic diagram showing an assembly process of the display module shown in FIG. 3;

FIG. 6 is a structure diagram of a protective member of the converter according to an example of the disclosure;

FIG. 7 is a structure diagram of a display screen assembly of the converter according to an example of the disclosure;

FIG. 8 is another cross-sectional structure diagram of the converter according to an example of the disclosure with part of components hidden;

FIG. 9 is a structure diagram of part A shown in FIG. 4;

FIG. 10 is a structure diagram of part B shown in FIG. 9; and

FIG. 11 is a structure diagram in which a light source assembly and a radar assembly are mounted on the surface cover.

### DETAILED DESCRIPTION

Technical solutions in the present disclosure will be clearly and fully described with reference to the accompanying drawings. Obviously, the examples to be described are merely part of the disclosure, but not all examples of the disclosure. Based on the examples of the disclosure, all other examples obtained by those of ordinary skill in the art without inventive work shall fall within the scope of the disclosure.

In a working process of the energy storage system and power generation system, electronic devices such as converters are often needed to convert electrical energy such as current. For example, converters are needed to convert between DC and AC. The converter can be equipped with a display screen to display various kinds of work-related information, but the current display effect of the display screen of the converter to display various kinds of work-related information needs to be improved. For example, internal components or structures of the converter corresponding to a non-display area can be seen. In order to solve the problem, the present disclosure provides the following examples.

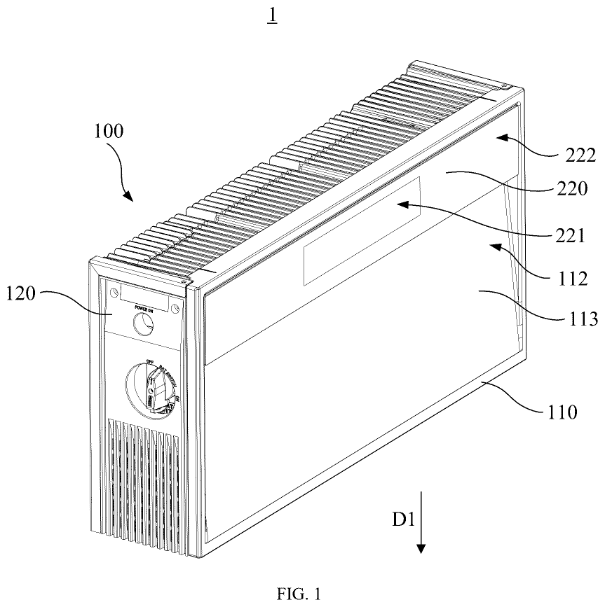

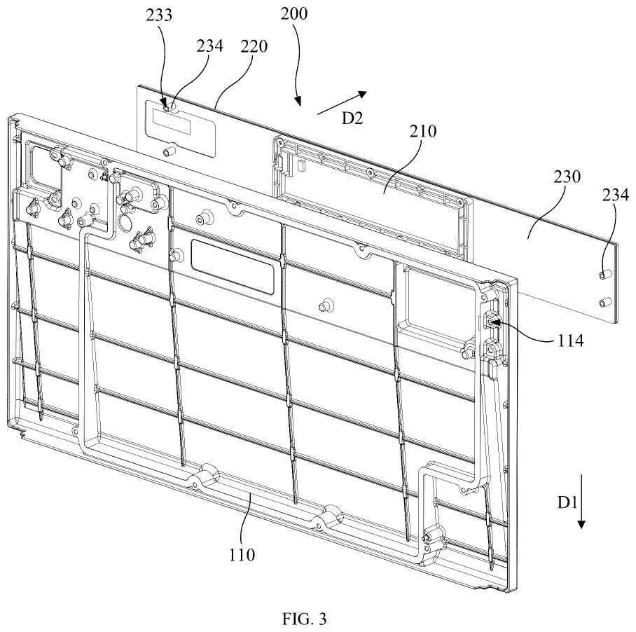

As shown in FIGS. 1 to 4, a converter 1 (e.g., a power converter) according to an example of the present disclosure includes a converter body 100 and a display module 200. The converter body 100 is configured to convert current, and a mounting groove 111 is provided on an outer side of the converter body 100. As shown in FIG. 3, the display module 200 includes a display screen assembly 210 and a protective member 220 (e.g., a protective layer, a glass layer, a plastic or resin cover, a metal frame, a screen protector). The display screen assembly 210 can be provided in the mounting groove 111, and the protective member 220 can be provided to cover the mounting groove 111.

The converter 1 may be an energy storage converter, an energy storage inverter, a power converter, or the like. For example, the converter body 100 can be configured to convert DC to DC, AC to AC, AC to DC, and DC to AC. The converter body 100 may comprise one or more circuits (e.g., circuitry) and the circuits may comprise transformers. The converter body 100 may be connected with an energy storage system, so as to manage a charging and discharging process of the energy storage system. The converter body 100 may be connected with one or more electrical equipment, so as to provide matching current for the electrical equipment. The converter body 100 itself may also have an energy storage unit (e.g., battery).

The protective member 220 may include a translucent area 221 and an opaque shielding area 222 which are adjacently to each other. The display screen assembly 210 is provided with a display area 211 which can be located corresponding to the translucent area 221, and a projection of the translucent area 221 toward the display screen assembly 210 may cover the display area 211.

In some examples, the translucent area 221 and the opaque shielding area 222 may present the same color. For example, both the translucent area 221 and the opaque shielding area 222 may be in black.

Further, the opaque shielding area 222 may be connected to an edge of the translucent area 221. For example, the opaque shielding area 222 may be adjacently provided around the edge of the translucent area 221.

The display screen assembly 210 may be configured to present a relevant working state of the converter 1 to one or more users. For example, the display area 211 can display working parameters of the converter 1, the electric quantity of the energy storage system or energy storage unit, a network connection state, and/or the like. The protective member 220 is located at a side of the display screen assembly 210 facing the outside, so as to protect the display screen assembly 210 and other components in the mounting groove 111 from mechanical damage, stain pollution, and other damage from the outside.

The translucent area 221 allows the light emitted from the display area 211 to pass through, so that a user can see the lighted characters displayed in the display area 211. The display area 211 is provided opposite to (e.g., corresponding to) the translucent area 221, and a projection of the translucent area 221 toward the display screen assembly 210 covers the display area 211 (e.g., a size of the translucent area 221 is the same as or larger than a size of the display screen assembly 210), which is conducive to clearly observing the information displayed in the display area 211 (e.g., when the user horizontally looks at the display area 211). The opaque shielding area 222 can shield an area irrelevant to the display information inside the mounting groove 111 to highlight the display effect of the display information and beautify the appearance of the converter 1. In addition, providing the opaque shielding area 222 makes the appearance of the converter 1 more elegant.

The display screen assembly 210 displays information by lighting characters, images and the like on the display area 211. By setting the translucent area 221 to be translucent, the translucent area 221 can allow the lighted characters and images on the display area 211 to be seen by users, and the translucent area 221 can also shield the unlighted characters and images on the display area 211, thus limiting visual interference caused by the unlighted characters and images and making the lighted characters and images stand out, thus improving the display effect of the display area 211 and facilitating the users to clearly observe the display information on the display area 211.

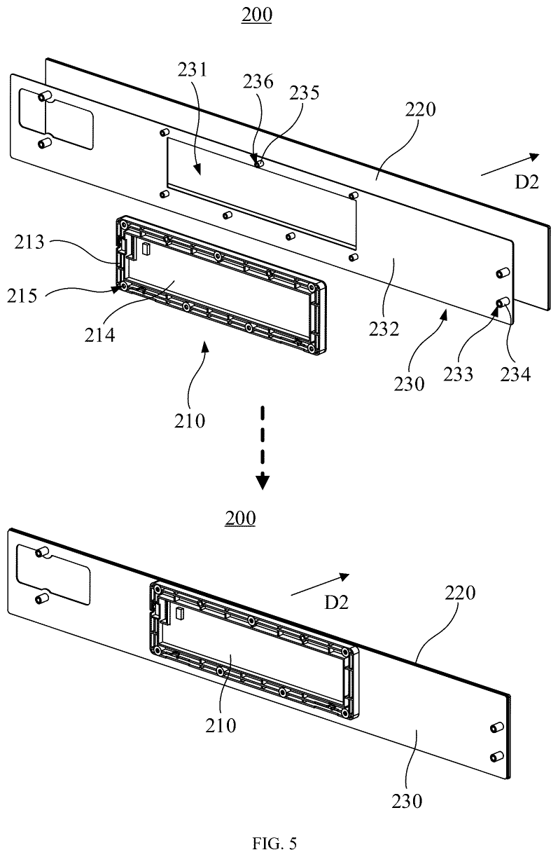

In some examples, as shown in FIG. 5, the display screen assembly 210 includes a display screen 214 and a frame 213 surrounding the display screen 214. The frame 213 can be used to support and fix the display screen 214, the display area 211 is provided on the display screen 214, and the opaque shielding area 222 can be used to shield the frame 213 for aesthetic effect.

In some examples, the display screen 214 is provided with a blank space around the display area 211, and the opaque shielding area 222 can be used to shield an outer edge of the blank space for aesthetic effect.

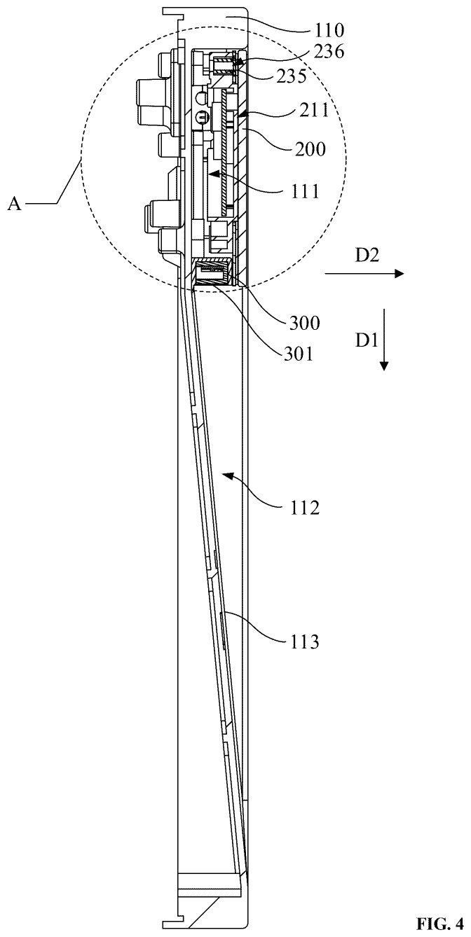

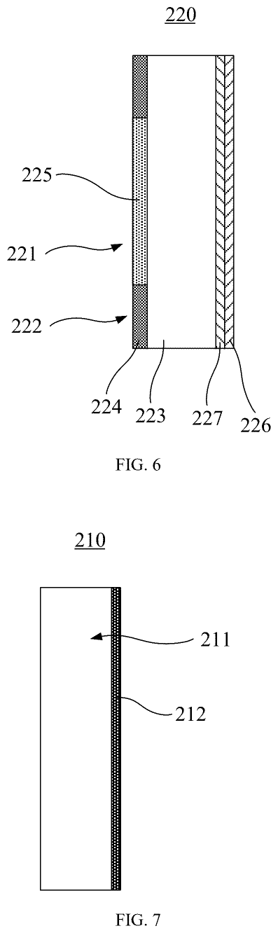

As shown in FIGS. 4 to 6, the protective member 220 includes a transparent substrate 223. The protective member 220 further includes a light shielding layer 224 covering an inner side of the transparent substrate 223 facing the mounting groove 111, and an area where the light shielding layer 224 covers the transparent substrate 223 forms the opaque shielding area 222.

By providing the light shielding layer 224, it is convenient for the protective member 220 to realize a light shielding function, and it is beneficial to simplify a production process of the protective member 220. For example, the light shielding layer 224 is an opaque black ink layer, and in the production process of the protective member 220, an area corresponding to the transparent substrate 223 can be coated with opaque black ink to form the opaque shielding area 222. As another example, the light shielding layer 224 is an opaque black film, and in the production process of the protective member 220, the opaque black film can be attached to an area corresponding to the transparent substrate 223 to form the opaque shielding area 222. In other examples, the light shielding layer 224 is black chemical plating. In other examples, the protective member 220 includes an opaque substrate that can be used as the opaque shielding area 222.

As shown in FIGS. 4 to 6, the protective member 220 further includes a translucent layer 225 covering an inner side of the transparent substrate 223 facing the mounting groove 111, visible light transmittance of the translucent layer 225 may be 5% to 25%, and an area where the translucent layer 225 covers the transparent substrate 223 forms the translucent area 221.

The light shielding layer is made of opaque material, and the translucent layer is made of translucent material. For example, the opaque material includes at least one of opaque black ink, opaque black film and black chemical plating; the translucent material includes at least one of translucent black ink or translucent film.

By providing the translucent layer 225, it is convenient for the translucent area 221 to achieve a translucent effect, and it is beneficial to simplify the production process of the protective member 220. For example, the translucent layer 225 is a translucent ink layer, and in the production process of the protective member 220, an area corresponding to the transparent substrate 223 can be coated with translucent black ink to form the translucent area 221. As another example, the translucent layer 225 is a translucent film, and in the production process of the protective member 220, the translucent film can be attached to an area corresponding to the transparent substrate 223 to form the translucent area 221. In other examples, the protective member 220 includes a translucent substrate that can be used as the translucent area 221.

The light shielding layer 224 may be provided around the translucent layer 225. In some examples, the transparent substrate 223 may be coated with opaque black ink to form the opaque shielding area 222, and the transparent substrate 223 may be coated with translucent black ink to form the translucent area 221, in which the opaque black ink is applied around the translucent black ink.

As shown in FIG. 7, the display screen assembly 210 includes a translucent film 212 attached to the display area 211, and visible light transmittance of the translucent film 212 may be 30% to 60%.

By providing the translucent film 212, it is possible to allow the lighted characters and images on the display area 211 to be seen by users and shield the unlighted characters and images on the display area 211, thereby improving the display effect of the display area 211. By attaching the translucent film 212 to the display area 211, it is beneficial to simplify the production process of the display screen assembly 210.

The color of the translucent film 212 may be black or silver gray. Further, the color of the translucent film 212 may be consistent with the color of the translucent layer 225.

The transparent substrate 223 is tempered glass. Thus, the protective member 220 can have good mechanical strength, chemical stability and service life, the protective effect of the protective member 220 on the display screen assembly 210 can be improved, and the protective member 220 itself is not easy to be scratched, age and discolor, which is beneficial to clearly display the display information on the display area 211 to users.

A thickness of the protective member 220 may range from 2 mm to 4 mm. For example, the thickness of the protective member 220 is 3 mm. Thus, the protective member 220 can have good mechanical strength and be light and thin.

As shown in FIGS. 4 to 6, an outer side of the protective member 220 facing away from the mounting groove 111 may be provided with at least one of an anti-fingerprint coating 226 and an anti-glare coating 227.

The anti-fingerprint coating 226 has small surface energy, a large contact angle, and good antifouling and waterproof performance, so that the protective member 220 can be restricted from being contaminated with a fingerprint, and thus the surface of the protective member 220 can be kept clean, which is beneficial to clearly display the display information on the display area 211 to the users. Specifically, the anti-fingerprint coating 226 can be formed on the transparent substrate 223 by AF (Anti-fingerprint) treatment.

The anti-glare coating 227 can have an effect of multi-angle diffuse reflection, thereby increasing a viewing angle of the display area 211 and reducing a problem that the protective member 220 reflects external light, which is beneficial to clearly display the display information on the display area 211 to the users. Specifically, the anti-glare coating 227 can be formed on the transparent substrate 223 by AG (Anti-glare) treatment.

In some examples, the outer side of the protective member 220 facing away from the mounting groove 111 is provided with the anti-fingerprint coating 226 and the anti-glare coating 227 simultaneously. In the production process of the protective member 220, the protective member 220 can be AG-treated to obtain the anti-glare coating 227, and then the protective member 220 can be AF-treated to obtain the anti-fingerprint coating, so that the anti-fingerprint coating covers the anti-glare coating 227.

In some examples, the protective member 220 can also form an anti-reflection coating by anti-reflection (AR) treatment to reduce the problem that the protective member 220 reflects external light.

As shown in FIGS. 3, 5, and 8, the display module 200 may further include a backing plate member 230 provided on the converter body 100, and the protective member 220 and the display screen assembly 210 are respectively provided on two opposite sides of the backing plate member 230. The backing plate member 230 is provided with a mounting hole 231, and the display area 211 is exposed to the translucent area 221 through the mounting hole 231.

By providing the backing plate member 230, it is convenient to connect the display screen assembly 210 with the protective member 220, and thus control a distance L1 between the display screen assembly 210 and the protective member 220 within a certain range, which is beneficial to clearly display the display information on the display area 211 to users.

The mounting hole 231 may penetrate the backing plate member 230 and be opposite to the translucent area 221. In some examples, the display screen assembly 210 is located outside the mounting hole 231, and the display area 211 is opposite to the mounting hole 231. In other examples, the display screen assembly 210 extends from the outside of the mounting hole 231 to the inside of the mounting hole 231, and the display area 211 is located outside and opposite to the mounting hole 231 or inside the mounting hole 231, which is beneficial to reduce the distance L1 between the display screen assembly 210 and the protective member 220, and thus clearly display the display information on the display area 211 to the users.

The backing plate member 230 is connected and fixed to the protective member 220 by sticking. Specifically, the backing plate member 230 may be connected and fixed to the opaque shielding area 222 by sticking.

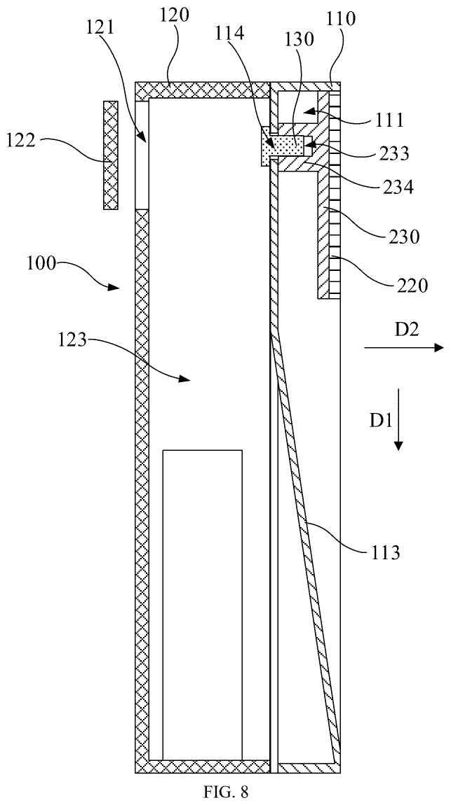

As shown in FIG. 8, the converter body 100 includes a surface cover 110 and a main housing 120, the mounting groove 111 is formed on the surface cover 110, and a side of the surface cover 110 facing away from the mounting groove 111 is connected with the main housing 120. The backing plate member 230 is detachably mounted on the surface cover 110 through a fixing member 130. The main housing 120 is provided with an avoidance hole 121 and a cover plate 122 detachably covering the avoidance hole 121. The avoidance hole 121 penetrates the main housing 120 and is opposite to the fixing member 130, and the fixing member 130 is exposed to the outside through the avoidance hole 121 after the cover plate 122 is detached.

The fixing member 130 passes through the surface cover 110. When the display module 200 needs to be detached or replaced, the cover plate 122 can be opened to expose the fixing member 130 through the avoidance hole 121, and then the fixing member 130 can be detached from the backing plate member 230, so that the display module 200 and the surface cover 110 are disconnected, and the display module 200 can be detached. Thus, the display module 200 can be detached without detaching the entire main housing 120 from the surface cover 110, and it is convenient to replace and maintain the display module 200.

Specifically, the surface cover 110 and the main housing 120 can enclose an accommodating cavity 123 which can accommodate various electronic devices of the converter 1 for converting current. The avoidance hole 121 communicates with the accommodating cavity 123. The fixing member 130 is a screw, the surface cover 110 is provided with a first connecting hole 114 therethrough, and a side of the backing plate member 230 facing the surface cover 110 is provided with a first threaded hole 233. The fixing member 130 passes through the first connecting hole 114 and extends into the first threaded hole 233 to connect the display module 200 and the surface cover 110.

Further, as shown in FIGS. 5 and 8, the backing plate member 230 includes a plate body 232 and a first connecting part 234 which protrudes from a side of the plate body 232 facing the surface cover 110, the first threaded hole 233 is provided at the first connecting part 234, and the display screen assembly 210 and the protective member 220 can be connected to two sides of the plate body 232. Thus, a thickness of the plate body 232 can be reduced, and occupied space of the backing plate member 230 can be reduced, which is beneficial to reduce the distance L1 between the display screen assembly 210 and the protective member 220.

There may be a plurality of first connecting parts 234 which are respectively provided at two ends of the plate body 232 along its own length direction. A plurality of first connecting holes 114 correspond to the first connecting parts 234 respectively.

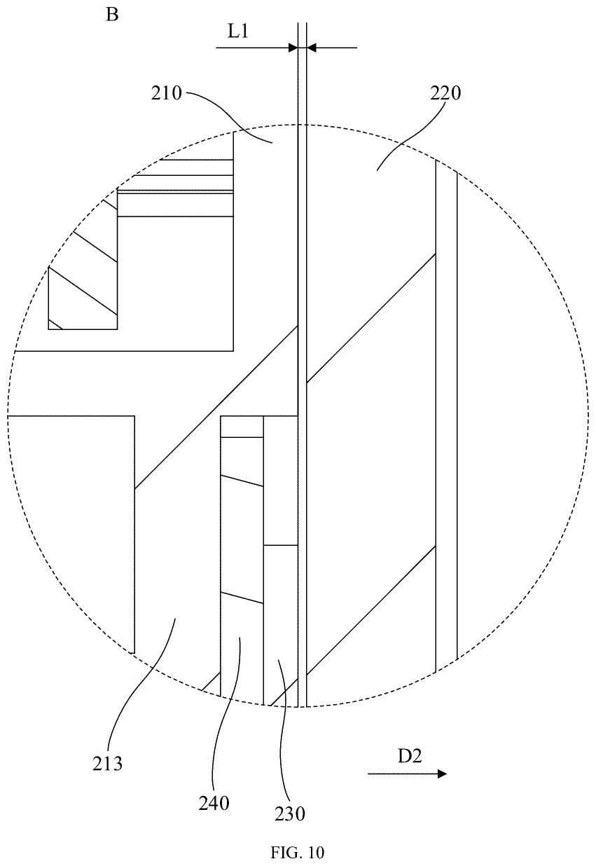

As shown in FIGS. 4, 9 and 10, the display screen assembly 210 may be provided with a frame 213 which is provided around the display area 211. The display module 200 further includes a sealing member 240 (e.g., foam gasket, adhesive seal, or silicone layer) which abuts between the frame 213 and the protective member 220. Specifically, the sealing member 240 abuts between the frame 213 and the opaque shielding area 222. Alternatively, the sealing member 240 abuts between the frame 213 and the backing plate member 230.

By providing the frame 213, pressure on the display area 211 can be reduced, which is beneficial for the display area 211 to present a good display effect. The sealing member 240 can limit water leakage and light leakage between the display area 211 and the protective member 220, which is beneficial to improve the display effect of the display area 211.

Further, the sealing member 240 can be made of flexible material, which can play a buffering role, reduce mechanical impact on the display area 211 during an assembly process or during mounting and use in application scenarios, and facilitate assembly of the display screen assembly 210 in place.

Further, as shown in FIG. 3 to FIG. 5, the backing plate member 230 includes a plate body 232 and a second connecting part 235 which protrudes from the side of the plate body 232 facing the surface cover 110 and is provided with a second threaded hole 236. The frame 213 is provided with a second connecting hole 215 therethrough, and a screw passes through the second connecting hole 215 and extends into the second threaded hole 236, so that the frame 213 and the backing plate member 230 are connected.

There may be a plurality of second connecting parts 235 which are distributed at intervals around the mounting hole 231. The second connecting holes 215 correspond to the second connecting parts 235, respectively.

As shown in FIGS. 4, 9 and 10, the distance L1 between the display screen assembly 210 and the protective member 220 may be less than or equal to 2 mm. Further, the distance L1 between the display screen assembly 210 and the protective member 220 may be less than or equal to 1 mm. For example, the distance L1 between the display screen assembly 210 and the protective member 220 may be 0 mm or 0.5 mm.

The smaller the distance L1 between the display screen assembly 210 and the protective member 220, the smaller the distance between the display area 211 and the protective member 220, and the clearer the display effect of the display area 211 to the outside. By setting the distance L1 between the display screen assembly 210 and the protective member 220 to less than or equal to 2 mm, it is beneficial to improve the display effect of the display area 211 to the outside.

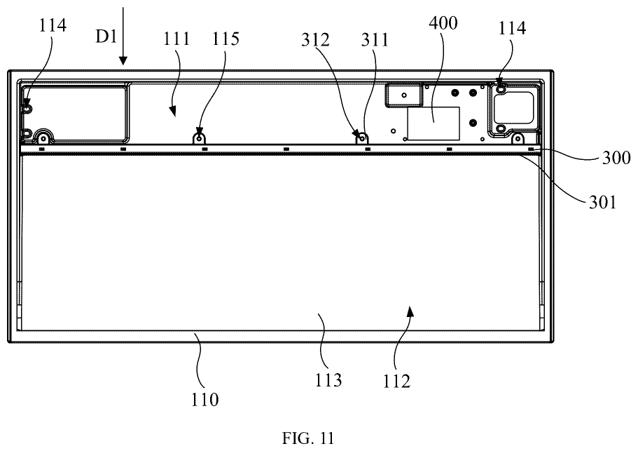

As shown in FIGS. 4, 9 and 11, the converter 1 may have a first direction D1 and a second direction D2 that intersect each other. The converter 1 further includes a light source assembly 300, a direction in which a light emitting surface 301 of the light source assembly 300 faces is the first direction D1, and a direction in which the display area 211 faces is the second direction D2.

When a user looks at the display area 211 horizontally, the display area 211 can face the user in the second direction D2, which is beneficial for the user to clearly observe the display area 211.

The light source assembly 300 can indicate a working state of the converter 1 by blinking, changing colors, or the like. When the user looks at the display area 211 horizontally, the light emitting surface 301 emits light in the first direction D1, so that a light emitting direction of the light emitting surface 301 is not toward the user's eyes, thereby not dazzling the user, reducing discomfort of the user's eyes, and facilitating the user to clearly observe the display area 211.

As shown in FIGS. 4, 9 and 11, the outer side of the converter body 100 is further provided with a reflective groove 112. The mounting groove 111 and the reflective groove 112 are located on the same side of the converter body 100, and are arranged and communicate in the first direction D1. The reflective groove 112 has a reflective surface 113 facing the outside, and the light source assembly 300 is provided in the mounting groove 111, and the light emitting surface 301 faces the reflective surface 113. In the first direction D1, the reflective surface 113 extends obliquely from a bottom of the reflective groove 112 to an opening of the reflective groove 112.

The light emitted by the light source assembly 300 may enter the reflective groove 112, then shine on the reflective surface 113, and then be reflected to the outside through the reflective surface 113. The user can look directly at the reflective surface 113 and observe a light emitting situation of the light source assembly 300 through the reflective surface 113. In this way, the user can clearly observe the light emitting situation of the light source assembly 300 without looking directly at the light source assembly 300.

Further, the light source assembly 300 can be shielded by the protective member 220, so that when the user looks at the display area 211 horizontally, the light emitting surface 301 cannot be seen.

A front the display area 211 faces along the first direction D1 may be an observation position, and the reflective surface 113 faces the observation position, so that the user can observe the display information on the display area 211 and the light emitting situation of the light source assembly 300 at the same time.

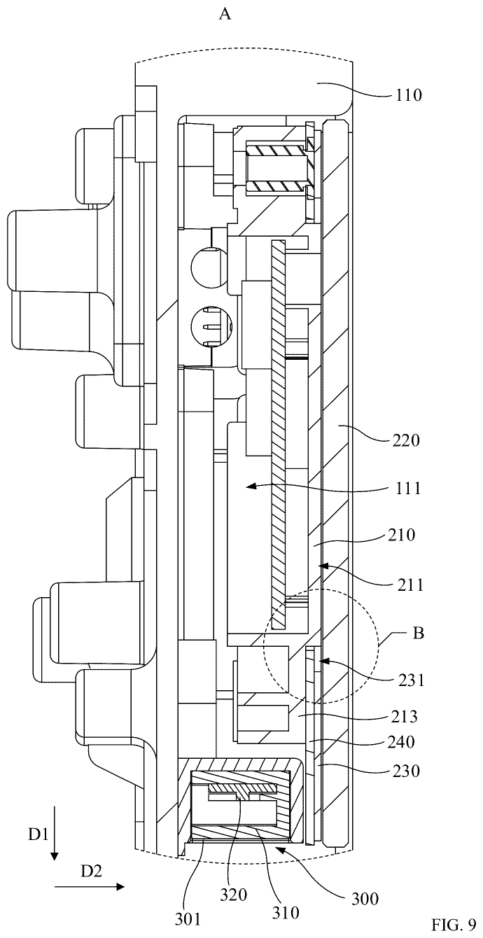

As shown in FIG. 9, the light source assembly 300 may include a mounting frame 310 and a tape light 320 which is provided inside the mounting frame 310, the light emitting surface 301 is located at a side of the tape light 320 facing the reflective surface 113, and a mounting part 311 protrudes from an outer surface of the mounting frame 310 and is detachably connected with the converter body 100 in the mounting groove 111.

Specifically, the tape light 320 can be provided in a strip shape, and the light emitting surface 301 extends along a length direction of the tape light 320, so that the area of the light emitting surface 301 can be increased. The tape light 320 may include a plurality of light beads, which contributes to enhancing diversity of luminous intensities and luminous forms of the tape light 320.

In the assembly process, first the light source assembly 300 and then the protective member 220 can be assembled on the converter body 100, so that the protective member 220 can protect the light source assembly 300.

Further, the surface cover 110 is provided with a third threaded hole 115, and the mounting part 311 is provided with a third connecting hole 312 therethrough. The screw passes through the third connecting hole 312 and extends into the third threaded hole 115, so that the light source assembly 300 is connected with the surface cover 110, thus facilitating the detachment of the light source assembly 300.

There may be a plurality of mounting parts 311 which are arranged at intervals along the length direction of the tape light 320. The third threaded holes 115 correspond to the mounting parts 311, respectively.

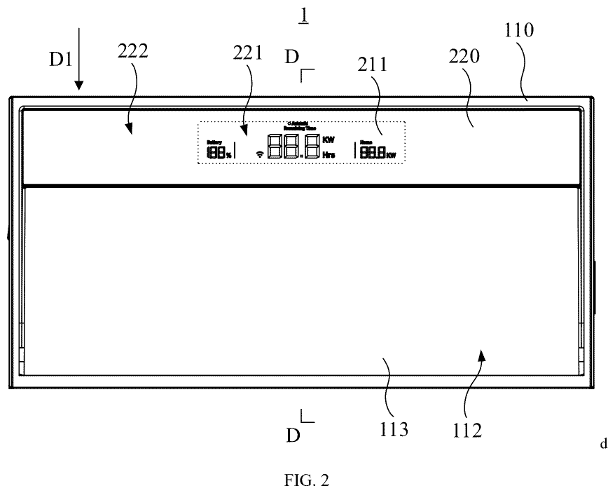

As shown in FIGS. 2, 3 and 11, the converter 1 further includes a radar assembly 400 (e.g., radar circuitry) provided in the mounting groove 111. The radar assembly 400 may include one or more antennas, duplexers, receivers, control circuit, and/or transmitters. The radar assembly 400 is electrically connected with the display screen assembly 210, and is configured to receive and/or send a signal for controlling on or off of the display screen assembly 210.

The radar assembly 400 can receive signals by radar sensing, and then trigger operation or shutdown of the display screen assembly 210. Different from a conventional key switch, by providing the radar assembly 400, a control mode of the display module 200 can be made more intelligent and flexible.

The radar assembly 400 can be electrically connected with the light source assembly 300, receive signals by radar sensing, and then trigger operation or shutdown of the light source assembly 300.

The present disclosure can shield assemblies or structures that do not need to be displayed inside the mounting groove 111 to beautify an appearance of the converter 1. By setting the translucent area 221 to be translucent, the translucent area 221 can allow the lighted characters and images on the display area 211 to be seen by users, and the translucent area 221 can also shield the unlighted characters and images on the display area 211, thus limiting visual interference caused by the unlighted characters and images and making the lighted characters and images stand out, thus improving the display effect of the display area 211 and facilitating the users to clearly observe the display information on the display area 211.

The above are only examples of the present disclosure and do not limit the scope of the disclosure. Any equivalent structure or process transformation made using the contents of description and drawings of the present disclosure, or direct or indirect use thereof in other related technical fields should be included in the scope of the present disclosure.

What is claimed is:

1. A power converter comprising:
converter circuitry configured to convert electrical energy;
a housing comprising a mounting groove; and
a display comprising:
a display screen provided in the mounting groove; and
a protective layer covering the mounting groove, wherein:
the protective layer has a translucent area and an opaque area adjacent to the translucent area,
the display screen comprises a display area located corresponding to the translucent area, and
a projection of the translucent area toward the display screen covers the display area.

2. The power converter of claim 1, wherein:
the protective layer comprises a transparent substrate and a light shielding layer covering part of an inner side of the transparent substrate facing the mounting groove, and an area where the light shielding layer covers the transparent substrate forms the opaque area,
the protective layer further comprises a translucent layer covering another part of the inner side of the transparent substrate facing the mounting groove, and an area where the translucent layer covers the transparent substrate forms the translucent area, and
the light shielding layer is made of opaque material, and the translucent layer is made of translucent material.

3. The power converter of claim 2, wherein visible light transmittance of the translucent layer is 5% to 25%.

4. The power converter of claim 1, wherein the display screen comprises a translucent film attached to the display area, and visible light transmittance of the translucent film is 30% to 60%.

5. The power converter of claim 1, wherein an outer side of the protective layer facing away from the mounting groove is provided with at least one of an anti-fingerprint coating and an anti-glare coating.

6. The power converter of claim 1, wherein:
the display further comprises a plate, and the protective layer and the display screen are respectively provided on two opposite sides of the plate;
the plate comprises a mounting hole; and
the display area is exposed to the translucent area through the mounting hole.

7. The power converter of claim 6, further comprising:
a surface cover, wherein:
the mounting groove is formed on the surface cover,
a side of the surface cover facing away from the mounting groove is connected to the housing, and
the plate is detachably mounted on the surface cover.

8. The power converter of claim 1, wherein
a distance between the display screen and the protective layer is less than or equal to 2 mm.

9. The power converter of claim 2, wherein:
the transparent substrate is tempered glass;
the opaque material comprises at least one of opaque black ink, opaque black film and black chemical plating; and
the translucent material comprises at least one of translucent black ink or translucent film.

10. The power converter of claim 1, further comprising:
a light source, wherein a direction in which a light emitting surface of the light source faces is a first direction, and a direction in which the display area faces is a second direction intersecting with the first direction.

11. The power converter of claim 10, wherein:
the housing is further provided with a reflective groove;
the mounting groove and the reflective groove are located on the same side of the power converter and are arranged and communicate in the first direction;
the reflective groove has a reflective surface, the light source is provided in the mounting groove, and the light emitting surface faces the reflective surface; and
the reflective surface extends, in the first direction, obliquely from a bottom of the reflective groove to an opening of the reflective groove.

12. The power converter of claim 11, wherein:
the light source comprises a mounting frame and a tape light provided inside the mounting frame,
the light emitting surface is located at a side of the tape light facing the reflective surface, and
a mounting part protrudes from an outer surface of the mounting frame and is detachably connected with the housing in the mounting groove.

13. The power converter of claim 1, further comprising:
radar circuitry configured to receive a signal for controlling on or off of the display screen.

14. A power converter comprising:
converter circuitry configured to convert electrical energy;
a display; and
a protective layer covering the display, wherein:
the protective layer comprises a transparent substrate, a light shielding layer, and a translucent layer, and
the display is configured to display information indicating a state of the power converter via the transparent layer.

15. The power converter of claim 14, wherein the protective layer has a translucent area and an opaque area adjacent to the translucent area.

16. The power converter of claim 14, wherein the light shielding layer covers part of an inner side of the transparent substrate and the translucent layer covering another part of the inner side of the transparent substrate.

17. The power converter of claim 14, wherein the display comprises a display area and a translucent film attached to the display area, and visible light transmittance of the translucent film is 30% to 60%.

18. The power converter of claim 14, wherein:
the transparent substrate is tempered glass;
the light shielding layer is made of opaque material; and
the translucent layer is made of translucent material.

19. The power converter of claim 14, further comprising:
a light source comprising a mounting frame and a tape light provided inside the mounting frame; and
a light emitting surface located at a side of the tape light, wherein
a mounting part protrudes from an outer surface of the mounting frame and is detachably connected with the power converter.

20. The power converter of claim 14, wherein visible light transmittance of the translucent layer is 5% to 25%.
